(19) United States
(12) Patent Application Publication
(10) Pub. No.: US 2007/0119495 A1
(43) Pub. Date: May 31, 2007

(54) Systems and Methods for Generating Electricity Using a Thermoelectric Generator and Body of Water

(75) Inventor: Theodore S. Sumrall, Fort Walton Beach, FL (US)

Correspondence Address: SUTHERLAND ASBILL & BRENNAN LLP, 999 PEACHTREE STREET, N.E., ATLANTA, GA, 30309, US

(73) Assignee: Theodore Sheldon Sumrall Trust, a Living Revocable Trust, Fort Walton Beach, FL (US)

(21) Appl. No.: 11/539,749

(22) Filed: Oct. 9, 2006

Related U.S. Application Data
(60) Provisional application No. 60/740,004, filed on Nov. 28, 2005.

(51) Int. Cl. H01L 35/30; H01L 35/28

(52) U.S. Cl. 136/205; 136/224

(57) ABSTRACT

A system for producing electrical power a thermoelectric generator including a thermopile, a hot junction, and a cold junction. A high temperature source may be thermally coupled to the hot junction wherein the high temperature source includes heat from within the earth's surface. A low temperature source may be thermally coupled to the cold junction wherein the low temperature source comprises cold water from a body of water. The thermopile generates electricity from a temperature gradient between the hot junction and the cold junction.

### RELATED APPLICATION DATA

The present application also claims priority to U.S. Provisional Application No. 60/740,004 entitled “Systems and Methods for Generating Electricity Using a Thermoelectric Generator” filed on Nov. 28, 2005, which is incorporated herein by reference in its entirety.

### GOVERNMENT CONTRACT

The U.S. Government has a license in this application pursuant to Contract Number F08630-03-C-0133 awarded by the U.S. Department of Defense.

### TECHNICAL FIELD

This application relates generally to the field of electricity generation through the use of heat from within the earth's crust and more particularly to the use of thermoelectric generators in combination with heat from within the earth's crust and cool fluid for electricity generation.

### BACKGROUND OF THE APPLICATION

Conventional systems for generating electricity for consumption and use by the public include nuclear power, fossil fuel powered steam generation plants and hydroelectric power. Operation and maintenance of these systems is expensive and utilizes significant natural resources and in some cases results in excessive pollution, either through hydrocarbon combustion or spent nuclear fuel rod disposal. Oil may be considered a non-renewable source of power, which leaves non-petroleum producing countries at the mercy of those which produce petroleum.

Nuclear power also has its problems. Currently, nuclear material is mined from the earth, refined and then utilized in a nuclear power plant. Sufficient amounts of Uranium-235 and/or plutonium are confined to a small space, often in the presence of a neutron moderator. The subsequent reaction produces heat which is converted to kinetic energy by means of a steam turbine and then a generator for electricity production. Nuclear power currently provides about 17% of the United States electricity and 7% of global energy. The cost for bringing a nuclear power plant on line is approximately $10-30 Billion. An international effort into the use of nuclear fusion for power is ongoing, but is not expected to be available in commercially viable form for several decades.

Therefore, there is a need in the art for systems and methods for generating clean electrical power cheaply without relying upon the import of petroleum materials or building of multi-billion dollar power plants.

### DETAILED DESCRIPTION OF THE DRAWINGS

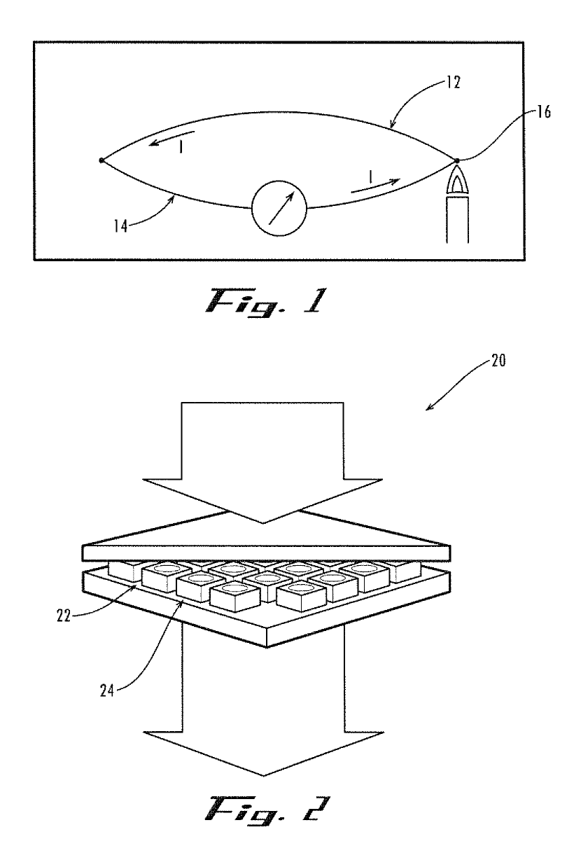

FIG. 1 is a diagram of the Seebeck Effect for thermoelectric systems according to an exemplary embodiment of the present application.

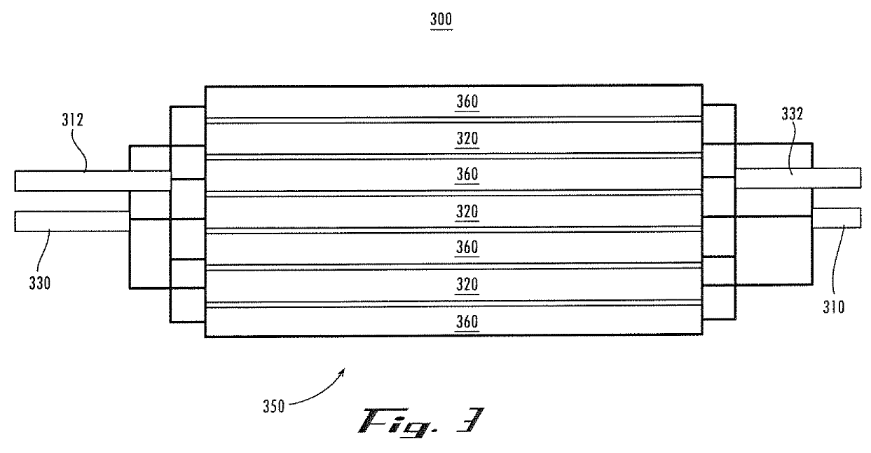

FIG. 2 is a thermopile of the thermoelectric system according to an exemplary embodiment of the present application.

FIG. 3 is a thermoelectric generator according to an exemplary embodiment of the present application.

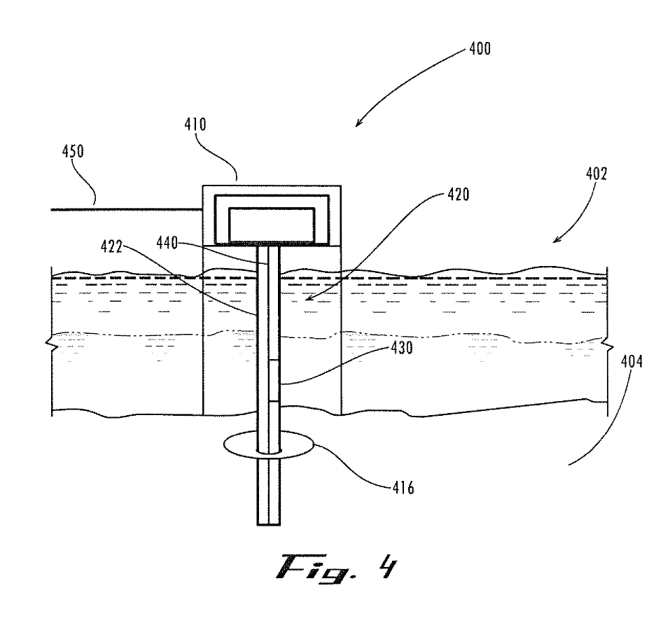

FIG. 4 is an illustration of a thermoelectric generation system according to an exemplary embodiment of the present application.

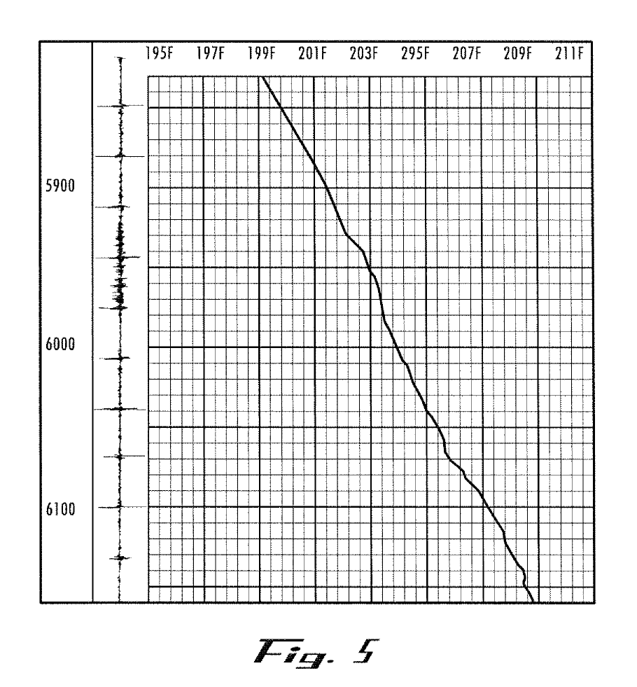

FIG. 5 is an illustration of temperatures within the earth's surface according to an exemplary embodiment of the present application.

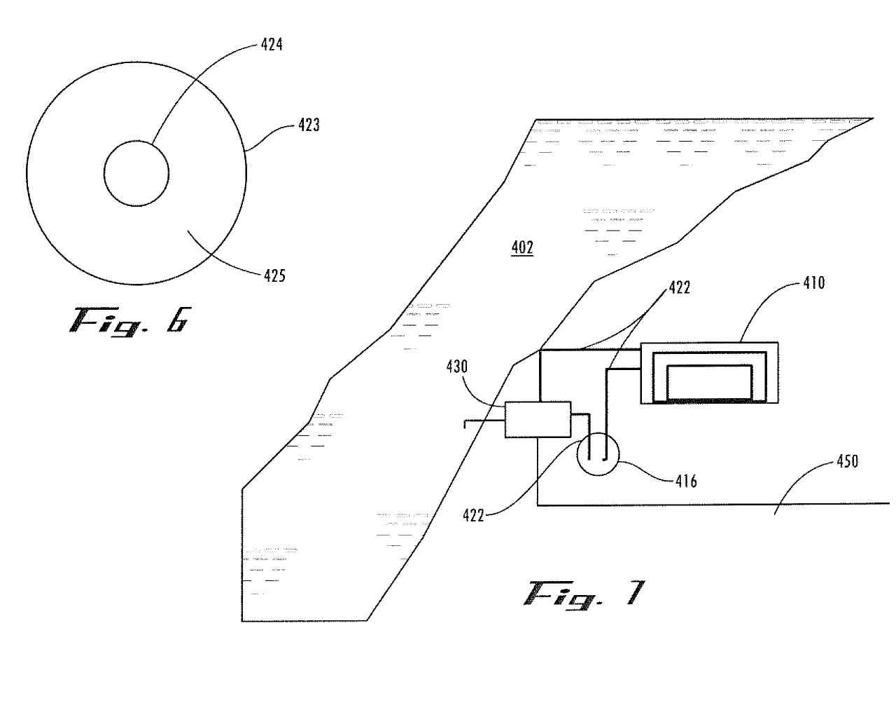

FIG. 6 is an illustration of a pipe including an interior pipe and an exterior pipe according to an embodiment of the present application.

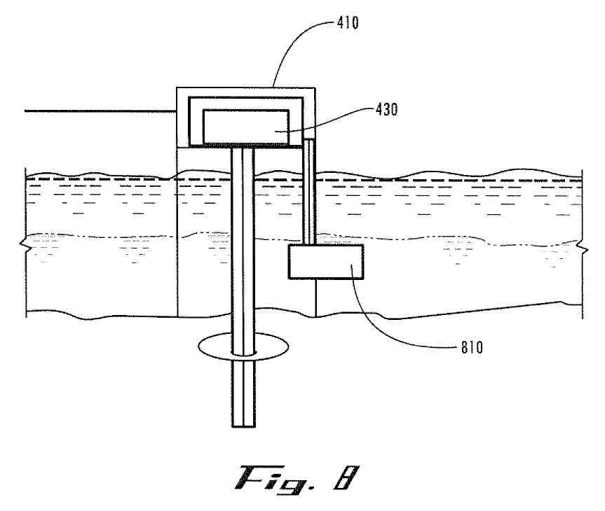

FIG. 7 is an illustration of a thermoelectric generation system according to an exemplary embodiment of the present application.

FIG. 8 is an illustration of a thermoelectric generation system according to an exemplary embodiment of the present application.

### DETAILED DESCRIPTION OF THE APPLICATION

The present application now will be described more fully hereinafter with reference to the accompanying drawings, in which an exemplary embodiment of the application is shown. This application may, however, be embodied in many different forms and should not be construed as limited to the embodiments set forth herein; rather, this embodiment is provided so that this disclosure will be thorough and will fully convey the scope of the application to those skilled in the art. Like numbers refer to like elements throughout.

As illustrated in FIG. 1, continuously flowing electrical current may be created when a first wire 12 of a first material is joined with a second wire 14 of a second material and then heated at one of the junction ends 16. This is known as the Seebeck Effect. The Seebeck effect has two main applications: Temperature Measurement (thermocouple) and Power Generation. A thermoelectric system is one that operates on a circuit that incorporates both thermal and electrical effects to convert heat energy into electrical energy or electrical energy to a decreasing temperature gradient. The combination of the two or more wires creates a thermopile 10 that is integrated into a thermoelectric system. When employed for the purposes of power generation, the voltage generated is a function of the temperature difference and the materials of the two wires used. A thermoelectric generator has a power cycle closely related to a heat engine cycle with electrons serving as the working fluid and can be employed as power generators. Heat is transferred from a high temperature source to a hot junction and then rejected to a low temperature sink from a cold junction or directly to the atmosphere. A temperature gradient between the temperatures of the hot junction and the cold junction generates a voltage potential and the generation of electrical power. Semi-conductors may be used to significantly increase the voltage output of thermoelectric generators.

FIG. 2 illustrates a thermopile 20 constructed with a n-typed semiconductor material 22 and a p-type semiconductor material 24. For increased electrical current, the n-type materials 22 are heavily doped to create excess electrons, while p-type materials 24 are used to create a deficiency of electrons.

Thermoelectric generator technology is a functional, viable and continuous long-term electrical power source. Due to the accessibility of temperature gradients occurring in natural and man-made environments, thermoelectric generators can provide a continuous power supply in the form of electricity. One of the most abundant, common, and accessible sources of energy is environmental heat, especially heat contained within the earth's crust

FIG. 3 illustrates an embodiment of the thermoelectric generator. The thermoelectric generator 300 may include an input 310 to a hot junction 320 and an output 330 to the hot junction 340. The hot junction 320 may include any source of heat for heat transfer. In an exemplary embodiment, the source of heat is a hot plate 340. The hot plate 340 may be metal or any other conductive material. The hot plate 340 may interface the thermopile 350 to provide heat to the thermopile through conduction, convection, radiation, or any other heat transfer means. One of ordinary skill in the art will appreciate that any thermoelectric generator may be used herein and is not limited to this embodiment. Any system that allows the heat to access the thermopile is contemplated herein.

The thermoelectric generator 300 may further include a cold junction 360. The cold junction 360 may include a cold plate 370 for heat transfer. Alternatively, heat may be radiated or convected away from the cold junction. The cold plate 370 may be metal or any other conductive material. The cold plate 370 may interface the thermopile 350 to provide a conductive heat sink. Voltage potential may be created across the thermopile 350 from a temperature gradient between the temperature of the hot plate 340 and the temperature of the cold plate 370. The greater the temperature gradient, the more electrical power may be generated. One of ordinary skill in the art will appreciate that any thermoelectric generator may be used herein and is not limited to this embodiment.

Any system that provides a heat sink that interfaces the thermopile is contemplated herein, including naturally occurring sources of heat absorption such as a fluid. In an exemplary embodiment, the fluid is water. Water may be obtained from any source including an ocean, sea, gulf, river, stream, creek, lake, spring, or from any underground source such as underground wells or from public water systems for the purposes of this application. Since the water is used to absorb heat, water from a public water system used as the heat sink herein may serve an ancillary purpose of preheating the water to decrease the power required by the public, government, or industry to heat the water for any desired use. Water or any fluid as the low temperature source provides a technical benefit over air or gas by having a higher heat transfer coefficient and therefore providing better heat transfer with the cold junction.

FIG. 4 illustrates an exemplary embodiment of a thermoelectric generation system 400. A thermoelectric generator may be used in the thermoelectric generation system to produce electrical power from a temperature gradient between a low temperature source and a high temperature source. The thermoelectric generation system 400 may be located in or near a body of water 402 including but not limited to an ocean, gulf, sea, lake, river, spring, creek, or any other relatively cooler body of water. The thermoelectric generation system 400 utilizes the body of water 402 as the low temperature source for the thermoelectric generator.

The body of water 402 can provide significantly lower temperatures to the thermoelectric generator to increase the temperature gradient. In a body of water 402, such as an ocean, gulf, sea, or lake, the temperature of the water decreases with depth. At a depth commonly referred to as the thermocline, the water temperature significantly decreases. The depth at which a thermocline occurs averages between 30 and 50 meters, and varies throughout the world. It is preferred for the low temperature source to be water at a depth below the thermocline to provide a continuous source of cold water, and preferably in a current to allow a continuous flow of cool water so that the water is not stagnant and therefore rises in temperature throughout energy production operations. Additionally, location of the power plant adjacent to some other surface body of relatively cooler water will allow the water to flow through the plant and then be discharged with minimal thermal change of the water.

The high temperature source may be provided from within the earth's crust 404. The earth provides a continuous, inexpensive source of extremely high heat. As illustrated in FIG. 5, the temperature within the earth generally increases towards the core of the earth at an average rate of approximately 1 degree Fahrenheit for every 60 feet of depth. Therefore, locations deep within the earth may be used as the high temperature source for the hot junction of the thermoelectric generator. Locations within the earth may be accessed through drilling or other means for creating a hole 416 in the ground and water or some other type of heat transfer medium circulated through the hole and brought to or near the surface to allow for heat transfer to occur by the employment of high efficiency pumps or some other method.

Certain holes, commonly referred to as dry holes may be used to access the high temperatures within the earth's crust. Dry holes typically exist from the unsuccessful efforts of the petroleum industry to locate oil or gas. The petroleum industry drills wells deep into the earth's crust for the exploration for petroleum. The overwhelming majority of exploration wells drilled throughout the world do not locate petroleum and are thereby indicated as “dry holes.” Dry holes provide relatively easy access to the subterranean levels and high temperature conditions. Dry holes may be located on land or in a body of water. Dry holes may reach depths in excess of 30,000 feet. However, one of ordinary skill in the art will appreciate that dry holes may be any depth. As shown in FIG. 5, temperatures in the dry holes can reach extremely high temperatures. In the exemplary embodiment of FIG. 5, temperatures in that particular dry well are approximately 209 degrees F. at 6100 feet. One of ordinary skill in the art will appreciate that this application is not limited to the use of dry holes and may include any hole in the earth's crust which can provide a heat source including holes drilled for use by a thermoelectric generator as well as expended oil and gas wells

Referring again to FIG. 4, the thermoelectric generation system may include a pump station 410, a pipe system 420, a thermoelectric generator 430, and a fluid 440. The thermoelectric generation system may be positioned in or proximate to a body of water 402. The pump station 410 may include a pump and associated housing for the pump. The pump may be any commercially available or specially designed pump that is capable of forcing fluid to flow at a suitable volumetric rate. The pump station 410 may be located on land, above the water surface, or underneath the water. The pump station 410 is connected to the pipe system 420. The pipe system 420 includes at least one pipe 422. The pipe 422 may include an inner bore for carrying fluid 440 to be heated by the earth. The inner bore may be any suitable diameter that allows sufficient fluid 440 to be pumped through the pipe system. The pipe 422 extends from the pump station 410 into the hole 416 and may be substantially U-shaped such that the pipe 422 ascends out of the hole.

The pipe system 420 may interface a hot junction 320 of the thermoelectric generator 430. The inner bore of the pipe 422 of the pipe system 420 is accessible to an input of the hot junction 320 of the thermoelectric generator 430. The pipe system 420 extends from an output of the hot junction 320 of the thermoelectric generator 430 to return to the pump station 410.

In another exemplary embodiment illustrated in FIG. 6, the pipe system may include an exterior pipe 423 and an interior pipe 424 such that an annulus 425 exists between the interior pipe 424 and the exterior pipe 423. In this exemplary embodiment, the fluid 440 may be pumped into the hole through the interior pipe 424, and the fluid 440 heated by the earth may be pumped out the hole through the annulus 425 to the hot junction 320 of the thermoelectric generator 430.

The fluid 440 is forced through the pump using the pump station 410. The fluid 440 is circulated through the pipe 422, the hot junction 320 of the thermoelectric generator 430, and the pump station 410 using the pump. Additional fluid may be added to the pipe system 420 either continuously or when needed by the system to account for any loss of fluid during operation of the pipe system and pump station. However, one of ordinary skill in the art will recognize that other methods of bringing the heated fluid to or near the surface may be employed.

The fluid 440 within the pipe 422 is heated by the earth as it descends from the pump station 410 towards the bottom of the hole 416. The fluid 440 may be heated to approach the temperature of the earth in the hole 416. In an exemplary embodiment, the fluid 440 may be heated in excess of 200 degrees Fahrenheit. After the fluid 440 reaches the lowest point of the pipe 422, the heated fluid then ascends out of the hole 416 and into the input of the hot junction 320 of the thermoelectric generator 430.

The heated fluid in the pipes 422 may be the high temperature source and is thermally coupled to the hot junction 320 of the thermoelectric generator 430. The fluid exits the inner bore of the pipe 422 and enters the input of the hot junction 320 of the thermoelectric generator 430. The fluid 440 then may exit through the output 330 of the hot junction 320 of the thermoelectric generator 430 through the inner bore of the pipe 422. The fluid 440 continues to the pump station 410 to close the pumping cycle of the fluid. The pump station may include any pump that is operable to pump the fluid 440 through the pipe system 420 and the thermoelectric generator 430 at an appropriate volumetric rate. Furthermore, the thermoelectric generation system may operate as either a closed system or an open system.

The fluid 440 may include any fluid that is capable of being heated by the earth and capable of retaining a substantial portion of the heat for delivery to the hot junction of the thermoelectric generator. In an exemplary embodiment, the fluid is water, however, other fluids may be employed to reduce corrosion and to allow heating well above the boiling point of water.

The thermoelectric generator 430 may be located in the body of water 402 and in communication with the pipe system 420. The body of water 402 is used as the low temperature source for the cold junction 360 of the thermoelectric generator. In the exemplary embodiment of FIG. 4, the thermoelectric generator 430 is located beneath the thermocline of the body of water 402 so that the cold junction 360 may access the low temperature water below the thermocline. In an exemplary embodiment, the thermoelectric generator 430 may be located in a current stream in the body of water 402 to access a flow of the water. The body of water 402 provides the low temperature source for cold junction 360 of the thermoelectric generator 430. The cold unction 360 may be outwardly exposed to the water in the body of water 402. The cold junction 360 may be sufficiently protected to prevent corrosion. The water in the body of water 402 also may be channeled into the cold junction 360 of the thermoelectric generator. The cold junction 360 may include an input for receiving the water and an output for exiting the cold water. The water may flow through the cold junction 360 to provide the low temperature source to the cold junction 360 of the thermoelectric generator.

In an exemplary embodiment, the high temperature source may be between 100 degrees Fahrenheit and 600 degrees Fahrenheit and the low temperature source may be between approximately 32 and 130 degrees Fahrenheit. One of ordinary skill in the art will appreciate that the high temperature source and low temperature source are not limited to these temperature ranges but may be any appropriate temperature ranges. The temperature gradient (ΔT) between the hot junction and the cold junction may be between 470 and 68 degrees in the exemplary embodiment. One of ordinary skill in the art will appreciate that the temperature gradient is not limited to this range but may be any temperature gradient.

The thermoelectric generator 430 creates a voltage potential across the hot junction 320 and the cold junction 360 of the thermoelectric generator. The use of the heat from the earth to control the temperature of the hot junction 320 and the coldness of the water to control the temperature of the cold junction 360 maximizes the temperature gradient and produces significant amounts of electrical power. The electrical power may be created as a direct current. The direct current may be transformed to an alternating current. A three-phase current may also be created. The electricity generated from the thermoelectric generator 430 may be transmitted through power lines 450 to any destination. In an exemplary embodiment, existing power transfer facilities and power conduction lines 450 may provide power to any current or newly created electrical grid network.

In another embodiment, the high temperature source may be used in conjunction with a steam powered generator. Fluid may be pumped through a pipe system into the earth's crust. The fluid may then be heated by the earth's crust and pumped to the surface. Using the high temperature source to heat the fluid may minimize the power required to operate a steam powered generator by preheating the water to the steam plants. The cost of heating the fluid to its boiling point, therefore, will be significantly reduced at hydrocarbon powered or other types of electrical plants if the fluid can be brought to a higher temperature as a result of heating within the earth's crust. For example, if the fluid is water, the high temperature source may heat the water to or near its boiling point. The water then could be converted to steam for use in the steam power generator. If the fluid is a fluid such as oil that has a boiling point greater than water, the fluid can be heated above 212 degrees Fahrenheit such that it can transfer heat through a heat exchanger to water in the steam powered generator to be converted to steam without the need of any or very little fossil fuels or other energy sources. The steam powered generator may be used in conjunction with the thermoelectric generation system or completely separate therefrom.

In another embodiment of the thermoelectric generation system illustrated in FIG. 7, the hole 416 may be located on the land proximate to a body of water. The hole 416 may provide the high temperature source for the hot junction as described previously. The body of water 402 may provide the low temperature source for the cold junction. The body of water 402 may be a river, spring, creek, lake, or any other cold water supply. The cold junction 360 of the thermoelectric generator 430 is thermally coupled to the body of water 402. The cold junction 360 may interface directly with the body of water 402 or the body of water may be directed to the cold junction 360 using a pipe 422 of a pipe system or other means of channeling the water such as a heat exchanger. The cold junction 360 is cooled to approximately the temperature of the water interfacing the cold junction. The thermoelectric generator 430 creates a voltage potential across the hot junction 320 and the cold junction 360 of the thermoelectric generator. The use of the heat from the earth to control the temperature of the hot junction 320 and the coldness of the surface or near surface water to control the temperature of the cold junction 360 maximizes the temperature gradient and produces significant amounts of electrical power through the employment of the thermoelectric modules. The electricity generated from the thermoelectric generator 430 may transmitted through power lines 450 to any destination.

In another embodiment of the thermoelectric generation system illustrated in FIG. 8, the low temperature source for the cold junction 360 may be water from a chiller device 810 residing below the surface of the earth. Due to the low temperatures below the earth's surface, the chiller device 810 may be used to lower the temperature of the water. In an exemplary embodiment, the chiller device may be placed at a depth up to approximately 300 feet below the surface. At approximately 300 feet below the surface, the temperature generally begins to increase with depth. One of ordinary skill in the art will appreciate that the 300 feet level is only an approximation and that the depth may vary depending on location on the earth and is therefore not limited to the 300 feet approximation. The chiller device 810 may be powered from electricity generated from the thermoelectric generator.

The utilization of water as the medium for heat transfer from deep within the earth's crust may cause corrosion of a metal pipe system. Hot water, especially when containing oxygen, may rapidly corrode metal. To reduce corrosion, a de-oxygenation mechanism, such as a high vacuum, may be employed to remove oxygen from the water. Alternatively, non-corrosive metals such stainless steel may be used for the pipe system. In another embodiment, the pipe system may include high temperature resistant and non-corrosive plastic piping. An exemplary embodiment of the plastic piping is piping manufactured from PARMAX™ materials. One of ordinary skill in the art will appreciated that any non-corrosive and temperature resistant plastic may be used. In yet another embodiment, corrosive preventative substances may be used to minimize corrosion. For example, chromates or other chemicals may be used. As an alternative to water, a non-corrosive fluid such as a synthetic oil may be used to absorb the heat from within the earth's crust for the high temperature source. Oil has the added advantage of being able to be heated to a higher temperature than water and therefore more power may be drawn from the thermoelectric generation system in this manner.

The thermoelectric generator must be protected from the low temperature source during operation to extend the life of the thermoelectric generator. Protection may be in the form of chemical protection or any other source. The cold junction may include ceramic materials to resist corrosion from the water. The thermoelectric generator also may be sealed such that water does not engage or corrode the thermopiles.

The thermoelectric generator may include off-the-shelf thermopiles. The thermoelectric generators also may employ specially designed thermopiles, such as Quantum Well Thermoelectric Generators, that will substantially increase power generation.

The thermoelectric generator also may employ nano wires to increase the efficiency of the system. The nano wires increases the density of states. The nano wires may be arranged in a substantially parallel array to transport generated electricity. The thermoelectric generator also may include quantum dots to increase the efficiency of the system and lowers the thermal conductivity of the system.

In another embodiment of the thermoelectric generation system, the high temperature source for the hot junction may be from a mud pit. Mud from the mud pit is used as a drilling fluid for oil well drilling. The mud extends to the bottom of the hole being drilled for oil exploration. The mud is heated from the drilling and the high temperatures from within the earth's surface. The hot junction of the thermoelectric generator may interface the mud pit to access the high temperature of the mud. The high temperature of the mud may be used to increase the change in temperature across the thermopile and to increase electrical generation.

The thermoelectric generation system may have several advantages over conventional systems of power generation. For example, the thermoelectric generation system has minimal pollution concerns due in part to its operation as a closed loop system and will rely upon minimal, if any, introduction of non-natural materials. The thermoelectric generation system will have minimal waste and minimal atmospheric emissions. The thermoelectric generation system also is completely renewable. The thermoelectric generation system also may be scaled down to a level which can provide power for a local area. The thermoelectric generation system may be inexpensive to construct and operate compared to conventional power systems and also may take advantage of non-producing oil wells instead of having to cap the wells that are non-productive or to drill new holes.

It should be apparent that the foregoing relates only to exemplary embodiments of the present application and that numerous changes and modifications may be made herein without departing from the spirit and scope of the application as defined herein.

1. A system for producing electrical power comprising:
a thermoelectric generator comprising a thermopile, a hot junction, and a cold junction;
a high temperature source thermally coupled to the hot junction wherein the high temperature source comprises heat from within the earth's surface;
a low temperature source thermally coupled to the cold junction wherein the low temperature source comprises water from a body of water; and
wherein the thermopile generates electricity from a temperature gradient between the hot junction and the cold junction.

2. The system of claim 1 wherein the high temperature source is selected from a group consisting of a dry hole, oil well, and gas well.

3. The system of claim 1, wherein the water is from a location below a thermocline of the body of water.

4. The system of claim 3, wherein the body of water is chosen from the group consisting of an ocean, sea, gulf, river, stream, creek, lake, stream, and spring.

5. The system of claim 1, wherein the body of water is water pumped from within the earth.

6. The system of claim 1, wherein the low temperature source is water from a public water supply.

7. The system of claim 1, further comprising:
a pipe system extending to the high temperature source and returning to the earth's surface; and
a fluid, wherein the fluid is pumped into the pipe system to access the high temperature source and heated by the high temperature source to be thermally coupled to the hot junction of the thermoelectric generator.

8. The system of claim 7, wherein the pipe system comprises a pipe comprising an interior pipe section and an exterior pipe section, wherein the fluid may be transported to the high temperature source through the interior pipe and transported from the high temperature source to the hot junction of the thermoelectric generator through an annulus formed between the interior pipe section and the exterior pipe section.

9. The system of claim 1, wherein the electricity generated is transmitted to a power station through power lines.

10. A system for pre-heating water for a steam powered generator comprising:
a high temperature source from within the earth's surface;
a pipe system extending to the high temperature source and returning to the earth's surface, wherein a fluid may be pumped into the pipe system to access the high temperature source and heated by high temperature source; and
wherein the fluid heated by the high temperature source is used to generate steam in a steam powered generator.

11. The system of claim 10 wherein the fluid is water.

12. The system of claim 11 wherein the water heated by the high temperature source is converted to steam in the steam power generator.

13. The system of claim 10 wherein the fluid has a boiling point higher than water.

14. The system of claim 13 wherein the fluid is heated above the boiling point of water and then passed through a heat exchanger to convert water into steam for the steam power generator.

15. A method for producing electrical power comprising:
providing a thermoelectric generator comprising a thermopile, a hot junction, and a cold junction;
thermal coupling the hot junction to a high temperature source wherein the high temperature source comprises heat from within the earth's surface;
thermal coupling the cold junction to a low temperature source wherein the low temperature source comprises cold water from a body of water; and
generating electricity from the thermopile through a temperature gradient between the hot junction and the cold junction.

16. The method of claim 15 wherein the body of water is chosen from group consisting of an ocean, sea, gulf, river, stream, creek, lake, spring.

17. A system for producing electrical power comprising:
a thermoelectric generator comprising a thermopile, a hot junction, and a cold junction; a high temperature source thermally coupled to the hot junction wherein the high temperature source comprises heat from within the earth's surface;
a low temperature source thermally coupled to the cold Junction wherein the low temperature source comprises cold water from a chiller located below the earth's surface; and
wherein the thermopile generate electricity from a temperature gradient between the hot junction and the cold junction.

18. The system of claim 17 wherein the chiller is located less than 300 feet below the earth's surface.

19. The system of claim 18 wherein the chiller uses electricity from the thermoelectric generator to operate.
